(19) United States
(12) Patent Application Publication
(10) Pub. No.: US 2007/0150786 A1
(43) Pub. Date: Jun. 28, 2007

(54) Method for coding, method for decoding, device for coding and device for decoding video data

(75) Inventors: Bruno Garnier, Saint Jean Sur Couasnon (FR); Frederic Pasquier, Laille (FR); Sylvain Fabre, Dinge (FR)

Correspondence Address: JOSEPH J. LAKS, VICE PRESIDENT;THOMSON LICENSING LLC, PATENT OPERATIONS, PO BOX 5312, PRINCETON, NJ, 08543-5312, US

(73) Assignee: Thomson Licensing

(21) Appl. No.: 11/636,035

(22) Filed: Dec. 8, 2006

(30) Foreign Application Priority Data
Dec. 12, 2005 (FR) 0553825

(51) Int. Cl. H04L 1/00; H03M 13/00; G08C 25/00; G06F 11/00; G06F 11/30

(52) U.S. Cl. 714/746

(57) ABSTRACT

The invention relates to a method and a device for coding video data comprising means for coding the pictures in data groups. According to the invention, the device comprises means for inserting, into the coded data groups, a message comprising parameters originating from the coding of the said group and allowing, during a subsequent decoding, a reconstruction of the said data in the event of error during the coding or during the decoding.

### FIELD OF THE INVENTION

The invention relates to a device and a method for coding and for decoding video data.

### BACKGROUND OF THE INVENTION

The development of compression standards has today led to the complexity of the coding algorithms.

It is now becoming important to be able to test the coding equipment, particularly when it has to comply with coding standards.

Particularly, in the context of the H.264 compression standard, the compression algorithms used are extremely complex. When the compression algorithms are generated by integrated circuits, it becomes difficult to understand at what level of the coding an error may occur, when a problem is detected in the decoder during the decoding phase. The coding of pictures being, for most of the pictures, dependent on the coding of other pictures, it is also difficult to determine in which picture the problem appears.

During the coding, it therefore becomes important to find mechanisms making it possible to mark, with the aid of additional information, the method of decoding in order to reveal at what level of coding or of decoding the problem occurred.

The detection of coding problems is desirable for the validation of the integrated circuits and also for the remote detection of problems at a client level.

### SUMMARY OF THE INVENTION

The invention proposes to solve at least one of the aforementioned problems. Accordingly, the invention proposes a video data coding device comprising means for coding the pictures in data groups. According to the invention, the device comprises means for inserting, into the coded data groups, a message comprising parameters originating from the coding of the group and allowing, during a subsequent decoding, a reconstruction of the data in the event of error during the coding or during the decoding.

According to a preferred embodiment, the means for coding the pictures in data groups comprise means for entropic coding, the parameters originating from the coding being relative to the entropic coding.

According to a preferred embodiment,
the means for coding the pictures in data groups code each picture in a slice,
the means for inserting the message into the coded data groups insert a message relating to each slice before each slice.

Preferably,
the means for coding the pictures in data groups code each slice in pixel macroblocks,
the coding parameters relating to each slice comprise parameters relating to each macroblock.

According to an advantageous feature, the message comprises an error correcting message computed on the uncoded data.

According to another advantageous feature, the means for inserting the message into the coded data groups insert a message relating to each slice before each slice and the error correcting message for each picture.

According to another aspect, the invention also relates to a data decoding device comprising means for decoding data in groups, each data group comprising at least one message comprising parameters originating from the coding of the said group and allowing, during the decoding, a reconstruction of the said data in the event of error during the coding or during the decoding. According to the invention, the decoding device comprises
means for extracting the message,
means for comparing the message with decoding parameters,
means for detecting an error during the decoding or during the coding according to the said comparison.

Preferably, the decoding device comprises means for entropic decoding of the data, the message comprising parameters relating to the entropic coding of the data groups, the means for comparing the message with decoding parameters compare the message with entropic decoding parameters

According to another aspect, the invention also relates to a video data coding method comprising a step for coding the pictures in data groups. According to the invention, the coding method comprises a step for inserting, into the coded data groups, a message comprising parameters originating from the coding of the group and allowing, during a subsequent decoding, a reconstruction of the data in the event of error during the coding or during the decoding.

According to another aspect, the invention relates to a video data decoding method comprising a step for decoding the data in groups, each data group comprising at least one message comprising parameters originating from the coding of the group and allowing, during the decoding, a reconstruction of the data in the event of error during the coding or during the decoding. According to the invention, the method comprises
a step for extracting the said message,
a step for comparing the said message with decoding parameters,
a step for detecting error during the decoding or during the coding according to the said comparison.

### BRIEF DESCRIPTION OF THE DRAWINGS

The invention will be better understood and illustrated by means for exemplary embodiments and advantageous applications, in no way limiting, with reference to the appended figures in which:

FIG. 1 represents a structure of the coded stream according to a preferred embodiment of the invention,

FIG. 2 represents a coding device according to a preferred embodiment of the invention,

FIG. 3 represents a decoding device according to a preferred embodiment of the invention.

### DETAILED DESCRIPTION OF PREFERRED EMBODIMENTS

The modules represented in the various figures are functional units that may or may not correspond to physically distinguishable units. For example, these modules or some of them may be combined in a single component, or constitute functionalities of one and the same software program. On the other hand, certain modules may, where necessary, consist of separate physical entities.

The description below is based on a data coding complying with the H.264 standard. This exemplary embodiment is not limited to a coding of this type. The invention in effect relates to any type of coding in which the information is inserted into the stream in order to make it easier to use subsequently.

“Data group” may be understood to be any breakdown into a data set. It may in particular be understood to be a group of pictures (GOP); it is also possible to understand slices of pictures.

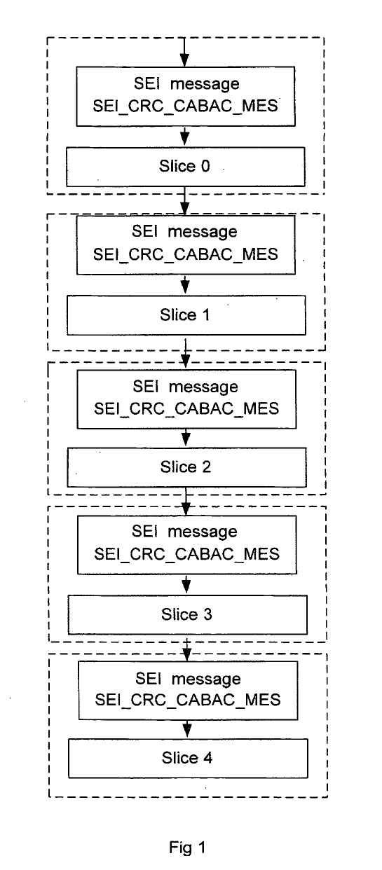

FIG. 1 shows the structure of the stream coded according to a preferred embodiment of the invention.

The pictures are coded in a broken down manner. Each picture is broken down into sections better known as slices. The breakdown into slices is decided during the coding. This breakdown into slices is carried out by the users of the coding device and particularly by the broadcasters of programmes.

According to this embodiment, an SEI message is inserted before each picture slice. The SEI message being indicated in FIG. 1 by SEI_CRC_CABAC_MES.

This SEI message comprises information relating to the coding and makes it possible, during the decoding of the slice to which it refers, to verify that the decoding is correct and, if this decoding is not correct, to be able to detect it to analyse it. When an error is detected, it is possible, for example, to replace the portion of the picture that is incorrect with the previously decoded picture.

For this purpose, the SEI message contains information relating to the coding of the entropic type carried out by the coding device. The nature of this information is specified later.

In the data stream, the SEI message may refer either to the preceding slice or to the next slice, depending on the implementation carried out in the coder. In the preferred embodiment, it refers to the slice that follows in the stream, the slice being stored before being transmitted.

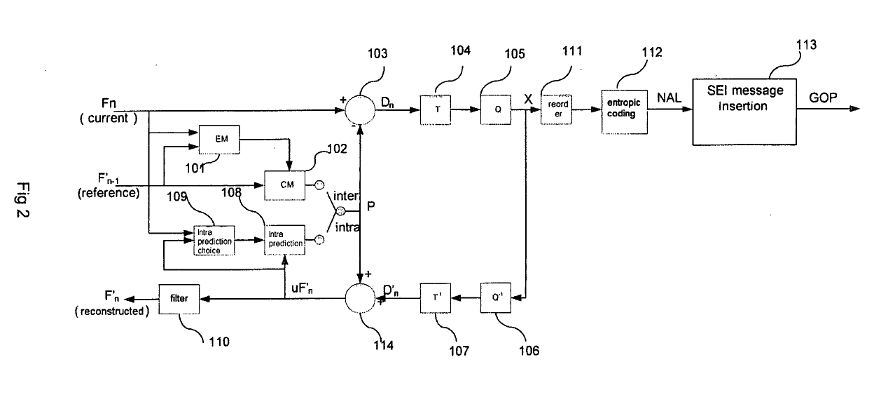

FIG. 2 represents a coding device according to the preferred embodiment of the invention.

A current frame Fₙ is. presented at the input of the coder to be coded therein. This frame is coded in the form of slices, that is to say that it is broken down into sub-units which each contain a certain number of macroblocks corresponding to groups of 16*16 pixels. Each macroblock is coded in intra mode or inter mode. Whether it is in intra mode or in inter mode, a macroblock is coded by being based on a reconstructed frame. A module 109 decides on the coding mode, in intra mode, of the current picture, according to the content of the picture. In intra mode, P (represented in FIG. 2) consists of samples of the current frame Fn that have previously been coded, decoded and reconstructed (uF′n in FIG. 2, u meaning unfiltered). In inter mode, P is made up of an estimate of movement based on one or more frames F′ₙ₋₁.

An estimate movement module 101 establishes an estimate of movement between the current frame Fn and at least one previous frame F′ₙ₋₁. Based on this estimate of movement, a movement compensation module 102 produces a frame P when the current picture Fn must be coded in inter mode.

A subtractor 103 produces a signal Dn, the difference between the picture Fn to be coded and the picture P. Then this picture is transformed by a DCT transformation in a module 104. The transformed picture is then quantized by a quantization module 105. Next, the pictures are reorganized by a module 111. An entropic coding module 112 of the CABAC (Context-based Adaptive Binary Arithmetic Coding) type then codes each picture.

Inverse transformation and quantization modules 106 and 107 respectively make it possible to reconstitute a difference D′n after transformation and quantization then inverse quantization and inverse transformation.

When the picture is coded in intra mode, according to the module 109, an intra prediction module 108 codes the picture. A picture uF′n is obtained at the output of an adder 114, as the sum of the signal D′n and of the signal P. This module 108 also receives at the input the unfiltered reconstructed picture F′n.

A filtering module 110 makes it possible to obtain the reconstructed filtered picture F′n from the picture uF′n.

The entropic decoding module 112 transmits the coded slices encapsulated in units of the NAL type. The NALs contain, in addition to the slices, information relating to the headers for example. The NAL type units are transmitted to a module 113. The module 113 inserts an SEI message before the transmission of the various coded picture slices to a transmission network.

An SEI message is inserted in order to obtain a stream as indicated in FIG. 1.

This message also comprises information relating to the entropic coding performed by the module 112.

The entropic coding module 112 uses a coding algorithm of the “cabac” type. The “codlLow” and “codelRange” parameters are parameters defined in the H.264 standard. These parameters are computed by the entropic coding module 112 for each slice. The SEI message therefore includes the values “codlLow” and “codelRange” relative to the coding of each slice.

The table below illustrates the payload portion of an SEI message, using a type 6 payload, corresponding, in the H.264 standard, to a payload of the “user_data_unregistered” type, represented in the table below.

Descriptor

user_data_unregistered(payloadSize){

| | |
|---|---|
| uuid_iso_iec_11578 | u(128) |
| for(i = 16; i < payloadSize; i++) | |

| | |
|---|---|
| user_data_payload_byte | b(8) |

}

the 128-bit word “uuid_iso_iec_{—}11578” indicates to the decoder the message type during the decoding phase. The H.264 standard specifies a certain number of values for this word according to its meaning. One of these values indicates that it is a message of the “user_data_payload” type.

the word “user_data_payload_byte” is an 8-bit word comprising a portion of the SEI message. These 8 bits are used to code the data relating to proprietary applications and particularly here for coding the data relating to the invention as coded below.

It is therefore possible to code, in this series of bytes, the values of codlRange and codlLow.

The values of CodlRange and CodlLow are each coded on 9 bits.

In addition to these data relating to the entropic coding, the SEI message contains an item of information of the error correcting code type (CRC for cycle redundancy check). This error correcting code is computed from the uncoded data. This error correcting code is computed using methods known to those skilled in the art and in particular using generating polynomials.

Advantageously, a CRC is inserted for each slice. The value of CRC is then coded with the values of CodlLow and CodlRange.

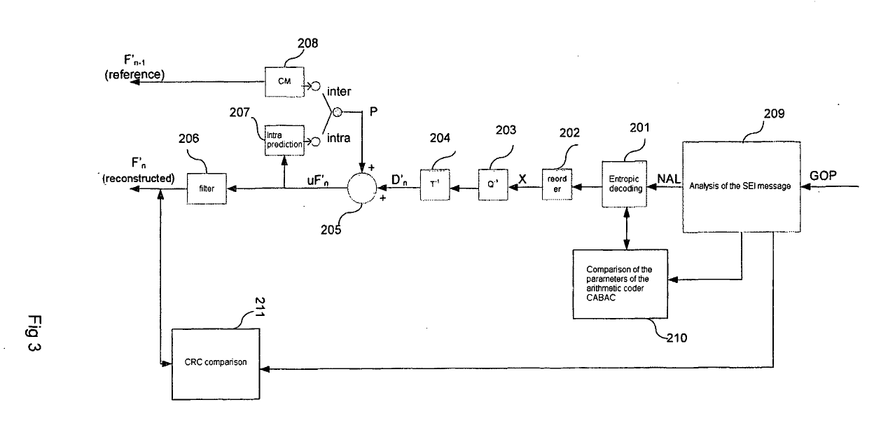

FIG. 3 represents a decoding device according to the invention.

A module 209 receives the SEI messages at the input. It extracts the various SEI messages and transmits them to a module 210 for comparison of the values relative to the entropic decoding and to a module 211 for CRC comparison of the values relating to the CRC. The payload data NALs are transmitted to an entropic decoding module 201.

The module 210 stores the incoming SEI message and compares the values of the CodelRange and CodelLow of the received slice with the values obtained during the arithmetic decoding carried out by the entropic decoding module 201. The entropic decoding module 201 carries out the inverse operation of the module 112 of FIG. 2. If the values CodelRange and CodelLow of the received slice are different from the values obtained during the decoding, then an error has occurred. This error is generated in the CABAC decoding if it is certain that the transport layer is reliable, or in the CABAC coding. In the test case, it is possible in particular to check that the transport layer is reliable. This therefore makes it possible advantageously to verify either a coder, or a decoder when it is known that the decoder, respectively the coder, is reliable.

The entropic decoding module then attempts to reconstruct the errored slice thanks to the values of CodelLow and CodelRange received and stored in the module 210.

During the entropic decoding, the arithmetic decoder values CodlLow and CodlRange are transmitted to the comparison module 210.

Then, the data are transmitted to a reordering module 202 in order to obtain a set of coefficients. These coefficients then undergo an inverse quantization in the module 203 and an inverse DCT transformation in the module 204 at the output of which the macroblocks D′n are obtained, D′n being a deformed version of Dn. A predictive block P is added to D′n by an adder 205 to reconstruct a macroblock uF′n. The block P is obtained after compensation of movement, carried out by a module 208, of the preceding decoded frame, during a coding in inter mode or after intra prediction of the macroblock uF′n, by a module 207, in the case of a coding in intra mode. A filter 206 is applied to the signal uF′n to reduce the distortion effects and the reconstructed frame F′n is created from a series of macroblocks.

A module 211 receives at the input a cyclic redundancy code (CRC) value extracted from the received SEI message and relating to the current slice. The CRC relates to the uncoded slice. The module 211 therefore computes the CRC relating to the slice that has just been decoded and compares this computed value with the value received from the module 209. If this comparison shows a difference between the two values, then it is known that there is an error during the decoding, if the transport layer is reliable.

According to another embodiment, the inserted SEI message comprises the codelRange and CodelLow values of the CABAC arithmetic module for each macroblock of the slice and not merely for each slice as in the preferred embodiment. CodlRange and CodlLow are each coded on 9 bits, so 14 bits remain for coding, on 32 bits, the block number. In HD (high definition) format, 8160 macroblocks are used per picture.

This then gives, for example, the following message as the SEI message.

| | CodlRange (9 bits), value after | CodlLow (9 bits), value |
|---|---|---|
| MB number | eos decoding | after eos decoding |
| 0 | Cir = 0x1e0 | Cio = 0x10e |
| 1 | Cir = 0x180 | Cio = 0x0be |
| 2 | Cir = 0x1b0 | Cio = 0x022 |
| 3 | Cir = 0x1c0 | Cio = 0x006 |

Advantageously, in the case of incorrect decoding, this makes it possible to define the macroblock that is errored and to recover it. Such granularity is therefore particularly effective but requires the CodelRange and CodelLow values for each macroblock of one and the same slice to be stored before they are sent simultaneously in the same SEI message.

In other embodiments, it is of course possible to insert one CRC per GOP or per picture but the granularity is less fine and the detection of errors is therefore made more difficult.

When one CRC is inserted per picture, it is for example inserted into the SEI message relating to the last slice of the picture.

When one CRC is inserted per group of pictures (GOP), it is for example inserted into the SEI message relating to the last slice of the last coded picture of the GOP.

1. Video data coding device comprising means for coding the pictures in data groups, wherein it comprises means for inserting, into the coded data groups, a message comprising parameters originating from the coding of the said group and allowing, during a subsequent decoding, a reconstruction of the said data in the event of error during the coding or during the decoding.

2. Device according to claim 1, wherein the means for coding the pictures in data groups comprise means for entropic coding, the said parameters originating from the coding being relative to the said entropic coding.

3. Device according to claim 1, wherein
the means for coding the pictures in data groups code each picture in a slice,
the means for inserting the said message into the coded data groups insert a message relating to each slice before each slice.

4. Device according to claim 3, wherein
the means for coding the pictures in data groups code each slice in pixel macroblocks,
the coding parameters relating to each slice comprise parameters relating to each macroblock.

5. Device according to claim 1, wherein the said message comprises an error correcting message computed on the uncoded data.

6. Device according to claim 5, wherein the means for inserting the said message into the coded data groups insert a message relating to each slice before each slice and the said error correcting message for each picture.

7. Data decoding device comprising means for decoding data in groups, each data group comprising at least one message comprising parameters originating from the coding of the said group and allowing, during the decoding, a reconstruction of the said data in the event of error during the coding or during the decoding, wherein it comprises
means for extracting the said message,
means for comparing the said message with decoding parameters,
means for detecting an error during the decoding or during the coding according to the said comparison.

8. Decoding device according to claim 7, wherein it comprises means for entropic decoding of the data, the said message comprising parameters relating to the entropic coding of the said data groups, the said means for comparing the said message with decoding parameters compare the said message with entropic decoding parameters.

9. Video data coding method comprising a step for coding the pictures in data groups wherein it comprises a step for inserting, into the coded data groups, a message comprising parameters originating from the coding of the said group and allowing, during a subsequent decoding, a reconstruction of the said data in the event of error during the coding or during the decoding.

10. Video data decoding method comprising a step for decoding the data in groups, each data group comprising at least one message comprising parameters originating from the coding of the said group and allowing, during the decoding, a reconstruction of the said data in the event of error during the coding or during the decoding, wherein it comprises
a step for extracting the said message,
a step for comparing the said message with decoding parameters,
a step for detecting error during the decoding or during the coding according to the said comparison.
